(19) United States
(12) Patent Application Publication
(10) Pub. No.: US 2014/0268527 A1
(43) Pub. Date: Sep. 18, 2014

(54) IMAGE REPRODUCTION ASSEMBLY HAVING A FRONT PANE FASTENED IN A SPACE-SAVING MANNER

(71) Applicant: Tridelity AG, St. Georgen (DE)

(72) Inventor: Johannes Sigwart, Hufingen (DE)

(73) Assignee: TRIDELITY AG, St. Georgen (DE)

(21) Appl. No.: 14/352,204

(22) PCT Filed: Oct. 30, 2012
(86) PCT No.: PCT/EP2012/071476

§ 371 Date: Apr. 16, 2014

(30) Foreign Application Priority Data
Nov. 2, 2011 (DE) 10 2011 085 613.7

(51) Int. Cl. H05K 7/00

(52) U.S. Cl. CPC H05K 7/00
USPC 361/679.01

(57) ABSTRACT

An image reproduction assembly having a two-dimensional image presentation matrix bounded by edges and by means of the matrix elements of which images are presented, fastening elements attached adjacent to edges of the matrix, a front pane fastened to the fastening elements, which is fixed in a plane in front of the image presentation matrix. Each fastening element protrudes beyond the plane of the image presentation matrix and partially beyond the edge of the image presentation matrix transversely to a viewing direction. Fastening elements are arranged along the edges so holes exist between fastening elements and/or adjacent to one or more fastening element. Fastening elements of a first image reproduction assembly can be positioned in holes of other image reproduction assemblies. Fastening elements of image reproduction assemblies adjacent to the first image reproduction assembly can be positioned in holes of the first assembly. Assemblies of image reproduction assemblies are provided.

The present invention relates to an image reproduction assembly with a front pane and an arrangement of several such image reproduction assemblies.

For a number of years there has been increasing use of large-format display systems for the visualisation of image contents. These large screens are increasingly replacing printed hoardings or advertisement surfaces. Depending on the size of the system, use is made of LCD technology, which has been widespread for many years, or, for very large surfaces, use is also made of LED technology.

LED and LCD image reproduction assemblies comprise an image presentation matrix, by means of the matrix elements of which images are represented. The matrix elements are in most cases arranged in lines and columns. With LCD image reproduction assemblies, for example, the matrix elements are different coloured subpixels, which in turn are grouped together to form pixels. As well as matrix elements, the image presentation matrix can also contain an electronic component, which actuates the matrix elements. In comparison with the image production matrix, the term “display” designates an image reproduction assembly which, as well as an image presentation matrix, also comprises further components, such as a controller, which takes charge of the signal processing, an inverter, which controls the background brightness, a power unit which supplies all the other components with voltage, and a housing into which the components are integrated.

Due to the technology involved, LCD's can only be manufactured in specific maximum numbers. By contrast, on the basis of LED technology, while it is true that large walls can be constructed, the technology involved means that, among other things, they have much poorer resolution related to a size unit (related, for example, to a surface unit, such as m²) than LCD displays.

In order to combine the advantages of both technologies, there have more recently been a number of large format LCD displays connected together, arranged next to and/or above one another, and actuated by special software. In this situation, each individual display then shows only the part of the total image content which is allocated to it. The arrangement of several displays shows the total image. The problem in this situation is that image production matrices are incorporated in a housing which is visible in the direction of the observer in the form of an edge or frame, which is usually circumferential. These frames do not contribute to the production of the image, and in particular do not comprise any matrix elements, and transverse the whole of the image surface of an arrangement of several image presentation matrices as interfering strips.

There are LCD image presentation matrices which are manufactured especially for video wall implementation purposes. They are designated as plain, seamless, or also narrow bezel displays, and allow for the creation of a video wall which is less optically impaired by interruptions.

There are different applications for displays, in particular LCD-based, which require the provision of a front pane in front of the image presentation matrix.

### a) Protective Pane

In applications, for example in public places, displays are in part required which are secured against vandalism, and for this purpose are provided with an impact-resistant and break-proof protective pane. For example, laminated glass elements protect an image presentation matrix behind them against damage.

### b) Touchscreen

In many applications, keyboard-free operation is required, for example by touchscreen. To achieve this, LCD displays are equipped, for example, with touch-sensitive glasses (referred to as touchscreens), these touchscreens then serving as input devices for the PC which is connected or integrated into the display.

### c) 3D Displays

The latest technologies offer the possibility of presenting specially prepared image contents spatially on LCD displays. This can be implemented on the one hand with the aid of spectacles (stereoscopic) or, on the other, without the need for spectacles (autostereoscopic). Both possibilities, however, require the provision of special filter panes in front of the image presentation matrix.

All three application examples can be used individually or partly also in combination with one another, and therefore have in common the factor that an additional pane must be located in front of the image presentation matrix. While the pane with a) and b) can be arranged relatively easily and without particular precision in front of the image presentation matrix, the pane for applications according to c) must be positioned exactly. This applies on the one hand to the alignment in the X and Y direction to the axis of vision, as well as to the distance (observed jointly) to the image presentation matrix (Z direction), as well as the angle about this Z axis. Deviations by fractions of a millimetre can have very negative effects on the perceivable image.

Due to the fact that the front panes, in particular for large-format displays, frequently exhibit a minimum thickness of about 3-5 mm, and that front panes, when glass is involved, have a high dead weight, stable mechanical securing and adjustment elements are required.

Known securing and adjustment elements for front panes are usually located laterally at the housing of an image presentation matrix. The housing appears, in the view of the observer, as a frame or edge around the image presentation matrix. By the lateral application of securing and adjustment means, the frame around the image presentation matrix is broadened, which with an arrangement of several displays together with one another leads to interfering lines between the image presentation matrices.

An object of the present invention is the provision of an image reproduction assembly with a front pane, with which it was intended that the edge regions protruding over the image presentation matrix should be minimized. With an arrangement of several image reproduction assembly next to and/or above one another in particular, the narrowest possible transitions should be visible between the image presentation matrices of the individual image reproduction assemblies.

In particular, it is intended that securing and adjustment elements for a front pane of an image reproduction assembly should be designed in such a way that the region of the securing and adjustment elements visible from the user's direction will appear as narrow as possible.

This object is solved by an image reproduction assembly according to claim 1.

Advantageous embodiments are presented in the subclaims.

An image reproduction assembly is proposed, comprising
a two-dimensional image presentation matrix, which is delimited by edges, and of which images can be presented by means of its matrix elements,
fastening elements located adjacent to the edges of the image presentation matrix,
a front pane, which is secured to the fastening elements and is fixed in a plane in front of the image presentation matrix,
   wherein each fastening element
protrudes at least partially beyond the plane of the image presentation matrix,
protrudes at least partially beyond the edge of the image presentation matrix, transverse to the viewing direction of an observer, and
   wherein the fastening elements are arranged along the edges in such a way that
recesses are present between fastening elements and/or adjacent to one or more fastening elements,
   and, with an arrangement of several such image reproduction assemblies next to and/or above one another
the fastening elements of a first image reproduction assembly can be positioned in the recesses of one or more image reproduction assemblies adjacent to the first image reproduction assembly, and
the fastening elements of one or more image reproduction assemblies adjacent to the first image reproduction assembly can be positioned in the recesses of the first image reproduction assembly.

A further object of the invention, which is solved by special embodiments, consists of being able to locate front panes as precisely as possible at a fixed defined distance in front of an image presentation matrix and adjusting them.

The image presentation matrix comprises matrix elements, also designated as segments, which are arranged in a uniform grid pattern. Particularly preferred is the arrangement in lines and columns.

The edges by which the image presentation matrix is surrounded can, for example, be part of a housing in which the image presentation matrix is located or which delimits the image presentation matrix. Preferably, the edges form a frame surrounding the image presentation matrix. The width of an edge amounts to, for example, about 2 to 10 mm, preferably 2 to 4 mm.

The fastening elements are located adjacent to the edges. In particular, they can be secured to the housing which surrounds the image presentation matrix and comprises edges which delimit the image presentation matrix.

The fastening elements can partially cover the edges of the image presentation matrix. The active image surface or matrix elements of the image presentation matrix are preferably not covered by the fastening elements, not even partially.

Each fastening element protrudes at least partially beyond the plane of the image presentation matrix. In other words, each fastening element comprises a protruding part, which protrudes beyond the plane of the image presentation matrix in the direction of an observer.

The term “fastening element” signifies, in particular, that the front pane is fastened to this element. The fastening element comprises at least one fastening point for the fastening of a front pane.

The securing mechanism is in no way restricted. The fastening element can be formed as one piece or several pieces. The fastening element can comprise, for the securing of a front pane, for example screws, in particular set screws, clamping elements, clamping strips, engagement positions, or plug-in elements, which can be removed.

The fastening element can be located on a carrier, for example on a profile strip, for example by screws or adhesive bonding, or it can be an integral part of a carrier, wherein the fastening element is formed as part of the carrier, i.e. represents a formed part of the carrier. The carrier is in turn arranged at the edge of the image presentation matrix, in particular secured at the edge of the image presentation matrix. A special embodiment of a profile strip with which this principle is realised will be described in greater detail hereinafter.

Arranged between the protruding parts of the fastening elements is the front pane. The fastening elements and their protruding parts respectively define a region in which the front pane can be moved and positioned in front of the image presentation matrix in the X and Y directions (transverse to the viewing direction of the observer). The fastening elements can be designed and arranged in such a way that the front pane is in contact with parts of its edge with the protruding parts of the fastening elements, without any gap. On the other hand, with the front pane in position, a gap may occur between the protruding parts of the fastening elements and the front pane. In this embodiment, the front pane is movable between the protruding parts. In this embodiment, the protruding parts define a region in which the front pane can be displaced parallel to the image presentation matrix. In this embodiment, the protruding parts form outer delimitations of the region. Inside the region, the front pane can be displaced transverse to the viewing direction of the observer, in any direction, until it comes in contact with one or more protruding parts. In this embodiment, the front pane can be positioned in the x-direction and y-direction (transverse to the viewing direction of the observer) exactly in front of the image presentation matrix, which is advantageous in particular for 3D applications and the front panes located there.

In a special embodiment, the protruding parts of the fastening elements are designed and arranged in such a way that a front pane located between the protruding parts can be rotated about an axis (z-axis) parallel to the viewing direction of the observer. A rotation capability is of advantage in particular for 3D applications and the front panes used in those situations. The capacity for displacement and/or rotation of the front pane between the protruding parts of the fastening elements can also be achieved, inasmuch as the pane is correspondingly dimensioned.

Preferably, each fastening element comprises a contact surface for the front pane. The protruding part of a fastening element can be arranged next to the contact surface for the front pane.

The fastening elements are arranged along the edges in such a way that recesses are present between fastening elements and/or adjacent to one or more fastening elements. A recess which is adjacent to a fastening element may extend, for example, from one end of the fastening element as far as an end of the edge, for example a corner in the case of a rectangular image presentation matrix. Recesses between fastening elements are in each case delimited by two fastening elements. A recess between two fastening elements may also be designated as a gap or intermediate space. The term “recess” in the meaning of the present invention does not necessarily mean that, at the location of the recess, material was removed from the edge, but may also signify that in this region of the edge no fastening element is arranged. Each fastening element protrudes at least partially beyond the edge of the image presentation matrix, transverse to the viewing direction of the observer. In the region of the recesses there is either no element protruding beyond the edge of the image presentation matrix, transverse to the viewing direction of the observer, or, in any event, there is an element or component present, of whatever function, which protrudes less beyond the edge of the image presentation matrix than a fastening element adjacent to the recess.

With an arrangement of several of the image reproduction assemblies next to and/or above one another, the fastening elements of a first image reproduction assembly engage into the recesses which are provided at the edges of adjacent image reproduction assemblies. Conversely, the fastening elements of adjacent image reproduction assemblies engage in the recesses which are provided at the edges of the first image reproduction assembly. This principle can be continued at will; i.e. with image reproduction assemblies adjacent to one another, the fastening elements of the one image reproduction assembly engage into the recesses of the other image reproduction assembly, and vice-versa. Preferably, one fastening element engages in one recess in each case.

With an arrangement of several of the image reproduction assemblies described next to and/or above one another, the fastening elements of the image reproduction assemblies are positioned offset to one another along adjacent edges, arranged parallel to one another, of adjacent image reproduction assemblies. When observed along the edges of adjacent image reproduction assemblies, arranged parallel to one another, a sequence of fastening elements is obtained, which are allocated alternately to the two adjacent image reproduction assemblies. Due to the arrangement of fastening elements in recesses, narrow transitions are obtained between the image presentation matrices of different image reproduction assemblies, if several image reproduction assemblies are assembled to form one superordinated assembly.

In a special embodiment, an image reproduction assembly is provided with which fastening elements arranged on opposite edges are arranged, point-symmetrical to one another, about a point which lies on the intersection of the two diagonals of the rectangular image presentation matrix. This embodiment is applied in particular with a rectangular image presentation matrix.

By means of this point-symmetrical arrangement, several image reproduction assemblies can be combined in a particularly simple manner to form an arrangement on several image reproduction assemblies.

In another embodiment, the fastening elements comprise clamp elements, which exert a closure pressure onto the front pane in the observer's direction of view. The clamp element can be applied to the fastening element as a separate part. In particular, such a clamp element is a clamp strip, which can be fixed to the protruding part of the fastening element, for example by one or more screws. In a further embodiment of an image reproduction assembly, the fastening elements are designed as L-shaped, wherein a limb of the L-shaped fastening element is located at the side of the housing of the image presentation matrix, wherein it can be in contact directly or indirectly with the housing, and a second limb is in contact directly or indirectly with the front pane, and exerts a closure pressure onto the front pane in the direction of the image presentation matrix. The term “indirectly in contact” means that an intermediate element can be inserted between the limb and the housing, or, respectively, between the limb and the pane. In a special variant, a profile strip is arranged between the first limb and the housing, which is described hereinafter. Between a second limb and the front pane one or more elastic, soft, and/or compressible intermediate layers may be provided, such as a rubber layer or cushion layer, or a securing material, such as a layer of adhesive.

The fastening element preferably comprises a contact surface for the front pane. The front pane lies on the contact surface with the side which is facing away from the observer. A clamping element, as referred to heretofore, preferably presses the front pane against the contact surface.

In a further embodiment, an image reproduction assembly is provided which comprises one or more spacer elements, by means of which the front pane can be positioned at a distance from the image presentation matrix. By means of the spacer element(s), a removed positioning of the front pane in front image positioning matrix can be achieved. The spacer element can extend from the edge of the image presentation matrix as far as a contact surface for the front pane. With this embodiment, the fastening element can comprise a spacer element or be arranged adjacent to a spacer element.

The front pane can consist, for example, of glass or plastic, such as Plexiglas. The front pane can be a protective pane, a pane of a touchscreen, or a pane for a 3D display, in particular a pane for an autostereoscopic 3D display with an optically active layer.

With one type of autostereoscopic display, front panes are used which comprise as the optically active layer an arrangement or grid of lenses or lens-shaped elements. Such front panes are described in DE 697 18 534 T2, and are also designated as lenticular panes or lens plates. A lens plate from DE 697 18 534 T2 extends essentially parallel to the plane of a reproduction plate as designated therein. It comprises an arrangement of longitudinal parallel lens elements, such that individual images which are represented by means of the reproduction plate can be perceived by the left and right eye of the viewer. If the image for the left eye and the image for the right eye correspond to the natural viewing angles when an object or a scene are observed, the viewer will perceive the representation produced on the reproduction plate as a three-dimensional representation.

Another variant of autostereoscopic display functions in accordance with what is referred to as the parallax barrier principle. With such 3D displays, the front panes comprise a layer with light-permeable and light-impermeable regions. The layer with the light-permeable and light-impermeable regions is also designated as a parallax barrier layer. The parallax barrier layer can be formed by a light-impermeable material being applied on one part of the rear of the front pane, which is facing the image presentation matrix, such that light-permeable regions are formed. The term “parallax barrier layer” therefore does not necessarily designate a layer which can be detached again from the front pane (such as, for example, an optically active film, which is located onto the plane), but can also designate a spatial plane with light-impermeable regions and light-permeable regions.

In one embodiment of the invention, the fastening elements comprise adjustment means, in order for the front pane to be capable of displacement and/or rotation parallel to the plane of the image presentation matrix. With such adjustment means it is possible in particular for a front pane for 3D displays to be brought into a desired position relative to the image presentation matrix. An example of an adjustment means is a screw, which is introduced into an opening of the securing means with an inner thread and can be unscrewed out of the fastening element in the direction of the front pane and, vice-versa, can be screwed back into the fastening element. The screw can be in contact with its end opposite the head, for example, at the edge of the front pane, such that, when the screw is rotated, the front pane is displaced. The screw can be directly in contact with the front pane, or intermediate elements, such as intermediate plates or strips, can be provided between the screw and the front pane, made in particular of deformable material, such that the screw can be in contact with the front pane directly or indirectly.

In one embodiment of the invention, an image reproduction assembly is provided, comprising profile strips which are arranged along the edges of the image presentation matrix, wherein each profile strip comprises a contact surface for the front pane, which is arranged parallel to the plane of the image presentation matrix, and wherein the fastening elements are located at the profile strips or are formed as an integral part of the profile strips. The fastening elements have in particular the form of a flank, which protrudes opposite the other parts or regions of the profile strip laterally and forwards in the viewing direction of the observer.

The profile strips serve as accommodation elements for the front pane. The contact surface for the front pane is preferably arranged on a face side of the profile strip facing the observer.

Each fastening element preferably protrudes beyond an edge of the profile strip, transversely to the viewing direction of an observer, and projects beyond the contact surface for the front pane in the viewing direction of the observer. Each fastening element preferably also protrudes beyond the other parts of the profile strip, transverse to the viewing direction of an observer. In particular, every fastening element protrudes beyond an edge of the profile strip which runs parallel to the edge of the image presentation matrix.

Preferably, the length of the profile strip corresponds to the length of the edge, or essentially to the length of the edge, to which it is allocated, such that the profile strips are in each case arranged along the entire length of an edge.

The profile strips can, for example, be secured to a housing of an image presentation matrix, for example by a screw, plug-in, or adhesive connection. The profile strip may comprise an edge which extends parallel along the edge of the image presentation matrix.

The profile strips can be arranged in such a way that they partially or wholly cover the edges of the image presentation matrix, from the view of the observer. In other words, they can project inwards in the direction of the image presentation surface, preferably without covering parts of the image presentation surface. The dimension which projects inwards is preferably selected such that the image presentation matrix is not impaired, and in particular such that no matrix elements of the image presentation matrix are covered by the profile strip.

The size of the front pane and/or the arrangement of the fastening elements is preferably selected in such a way that the surface area delimited by the fastening elements is greater that the surface area of the front pane, such that it is possible for the pane to be rotated about the Z-axis, in order to align it relative to the image presentation matrix.

If, for example, with a pane with dimensions of 1340×760 mm, it is intended that a rotation of 0.5° should be made possible, then the area delimited by the fastening elements should exhibit dimensions of at least approx. 1347×772 mm. The size of the pane and/or the arrangement of the fastening elements is preferably also chosen in such a way that it is possible for the pane to be displaced on the X-axis and/or the Y-axis, in order for it to be aligned relative to the image presentation matrix.

The term “area delimited by fastening elements” does no necessarily mean that the fastening elements surround this area without any gaps being left. What is meant is a surface area which is at least partially delimited by fastening elements, and within which the front pane can be rotated about the Z-axis (viewing direction of the observer) and/or displaced about the X and Y-axis. A part of the delimited surface is arranged as a contact surface. During the rotation and displacement, the front pane is rotated and/or displaced on the contact surface of the profile strips.

In one embodiment, the profile strips comprise spacer elements, by means of which the front pane can be positioned at a distance from the image presentation matrix. The spacer elements can be a part of the fastening elements at the profile strips, or they can be arranged at another location on the profile strips. Preferably, the contact surfaces for the front pane are arranged in each case on the face side of a spacer element. The length of the spacer elements in the direction of the user (Z-axis) is selected in such a way that it corresponds to the desired distance interval between the image presentation matrix and the front pane. The desired distance interval is dependent, for example, on the type of the image presentation matrix, the area of application, and the requirement for use.

In one embodiment, the profile strips comprise fastening elements with clamping elements, wherein the clamping elements exert a pressure onto the front pane in the direction of the image presentation matrix. The clamping elements can be brought in contact with the fastening elements and exert a pressure onto the front pane in the direction of the image presentation matrix or, respectively, in the viewing direction of the observer. The clamping elements are preferably detachable, in order to be able to insert or clamp a pane, and also capable of being transformed into a clamping state, in which the front pane is clamped tight and fixed. The clamping element can be, for example, a clamping strip, which is applied at the profile strip, in particular the fastening element, for example, with a screw connection, and which presses the front pane against its contact surface at the profile strip.

Like the fastening elements, the clamping elements, as part of the fastening elements, are designed in such a way that, with an arrangement of several image reproduction assemblies next to one another and/or above one another, are arranged not directly opposite but rather alternating, offset to one another, such that the added thickness of the fastenings between two adjacent image reproduction assemblies contributes only once to the broadening of the transition between two image presentation matrices (non-symmetrical arrangement on the two opposite sides of an image presentation matrix).

A slippage-inhibiting material can be located at the profile strips, in particular on the contact surfaces for the front pane and at the clamping elements, in order to provide for a secure seat of the front pane. Inherently loose slippage-inhibiting material can also be inserted between the pane and the profile strip.

The profile strips can be designed in such a way that they comprise several flanks as fastening elements arranged on the outside, the height of which preferably exceeds the dimension of the profiles by the thickness of the pane plus the slippage-inhibiting material, inasmuch as this is present. The flanks serve on the one hand as an outside delimitation for the pane positioning, and, on the other, as a fastening point for clamping elements to be fastened on it. In addition to this, one can be allocated to the flanks of adjusting elements for the pane, as described heretofore.

In one embodiment, the fastening elements which can be attached to the profile strips are an L-shape (angle), wherein the fastening element is located by a first limb of the L, preferably a longer limb, laterally to the profile strip, such that this longer limb forms a lateral flank. For example, the longer limb can be screwed or adhesively bonded to the profile strip. The other, second limb of the L, preferably a shorter limb, exerts a pressure onto the front pane in the direction of the image presentation matrix. The second limb is in contact from the outside on the front pane, and presses the front pane against the profile, i.e. against the contact surface at the profile. The longer, lateral limb is preferably screwed to the profile, and comprises, for example, a longitudinal hole, such that it can be displaced along its fastening point, as a result of which it can be brought into such a position that is presses the front pane in the manner described heretofore. The fastening element is therefore preferably detachable from the profile strip, i.e. capable of being reversibly brought into contact, and preferably displaceable at least relative to the profile strip along the viewing axis of the observer. A soft slippage-inhibiting material can be arranged between the second limb and the front pane. Likewise, a soft slippage-inhibiting material can be arranged between the profile strip and the front pane. If such a material is arranged between the profile strip and the front pane, a surface of the material then forms a contact surface for the front pane, if the material is regarded as a part of the profile strip, or this material lies on the contact surface of the profile strip, and can be regarded as a part of the front pane.

In one embodiment, identical profile strips are arranged along opposing edges, preferably of the same length, of the image positioning matrix. The profile strips are arranged point-symmetrical to one another about a point which lies on the intersection of the two diagonals of the rectangular image positioning matrix. In other words, profile strips located opposite one another in an image presentation matrix are rotated in relation to one another by 180° about the Z-axis. This embodiment is particularly advantageous with a rectangular image presentation matrix. With a rectangular image presentation matrix, the profile strips and the clamping elements to be applied to them are only present in two embodiments, a longer embodiment for the opposing longitudinal sides of the matrix, and a short embodiment for the opposing wide sides of the matrix.

Finally, the invention also relates to an arrangement of several image reproduction assemblies, as described heretofore, wherein several image reproduction assemblies are arranged next to one another and/or above another, such that the individual image presentation matrices of the image reproduction assemblies are assembled to form an enlarged image presentation matrix. The composition and arrangement of the fastening elements with adjacent image reproduction assemblies is carried out in accordance with the principles described heretofore.

The invention is described hereinafter on the basis of special embodiments. These show:

FIG. 1 a front view of a part of a rectangular image presentation matrix with circumferential edges;

FIG. 2 a front view according to FIG. 1, with profile strips fitted;

FIG. 3 a front view with profile strips fitted as in FIG. 2 and a front pane laid on them;

FIG. 4 a view according to FIG. 3, wherein the front pane is secured with clamping strips;

FIG. 5 the assembly similar to FIG. 2, from a perspective obliquely from the side;

FIG. 6 the assembly according to FIG. 4, from a perspective obliquely from the side;

FIG. 7 a section from an image reproduction assembly in a view from obliquely above;

FIG. 8 a section from an image reproduction analogous to FIG. 6, viewed from above or below (Y-direction);

FIG. 9 an alternative embodiment of a profile strip with L-shaped fastening element viewed obliquely from above;

FIG. 10 an alternative embodiment of a profile strip with L-shaped fastening element viewed obliquely from above or below (Y-direction);

FIG. 11 a section from an arrangement of several image reproduction assemblies in a frontal view; and

FIG. 12 a further section from an arrangement of several image reproduction assemblies, wherein one image reproduction assembly is fully shown.

FIG. 1 shows the observer's view of an image presentation matrix 1. The observer's view is in the z-direction, and the x-direction and y-direction are drawn in at the bottom left in FIG. 1. Shown is a section from a rectangular image presentation matrix 1 in the region of the upper right corner. The image presentation matrix 1 is surrounded by the edges 2, 3, and the edge 4 which is not shown (lies opposite edge 2 and runs parallel to edge 2) and 5, not shown (runs parallel to edge 3 and opposite edge 3). The edges 2, 3, 4, 5 are part of a housing of the image presentation matrix 1.

FIG. 2 shows profile strips 15, 16, arranged at the edges 2 and 3, wherein the profile strips are also only shown as certain sections. Further profile strips 17, 18 are arranged in each case at the edges 4, 5 (not shown, but see FIG. 12). The profile strip 15 comprises a contact surface 19, and the profile strip 16 a contact surface 20, which faces the observer and on which a front pane can be laid (see FIG. 3). The profile strips 15, 16 and their contact surfaces 19, 20 respectively partially cover the edges 2 and 3, as can be seen in comparison with FIG. 1. A fastening element 6 is formed at the profile strip 15, and a fastening element 7 is formed at the profile strip 16. The profile strips 15, 16 comprise further fastening elements, which are not shown in this figure, which only represents a section. The fastening element 6 also protrudes beyond the plane of the image presentation matrix 1. The fastening element 6 also protrudes beyond the contact surface 19 in the direction of the observer. The fastening element 7 protrudes towards the observer beyond the plane of the image presentation matrix 1. The fastening element 7 also protrudes beyond the contact surface 20 in the direction of the observer (out of the plane of the image) (see FIG. 5).

FIG. 5 shows a side view of the assembly according to FIG. 2, with the profile strip 16, but without the profile strip 15. By way of the profile strip 16 it can be seen that the fastening element 7 is a flank projecting in the z-direction, which rises from the remainder of the profile strip 16. As can be seen in FIGS. 2 and 5, the fastening element 7 protrudes transversely to the viewing direction of the observer (the z-direction) in the x-direction beyond the edge 3 of the image production matrix 1. In an analogous manner, the fastening element 6, which is likewise formed as a side flank of the profile strip 15, protrudes in the x-direction beyond the edge 2. Further parts of the profile strips 15, 16 protrude beyond the edges 2, 3, but the fastening elements 6, 7, protrude further in the x-direction and y-direction respectively than the other parts of the profile strips 15, 16. The profile strip 15 comprises an edge 31, which runs parallel to the edge 2 of the image presentation matrix. The fastening element 6 protrudes in the y-direction beyond this edge 31. The profile strip 16 comprises an edge 30, which runs parallel to the edge 2 of the image presentation matrix. The fastening element 7 projects in the x-direction beyond the edge 30.

FIG. 3 shows the arrangement from FIG. 2, with the difference that a front pane 10 is located on the contact surfaces 19, 20 of the profile strips 15, 16 and the contact surfaces 21, 22 of the profile strips 17, 18 (not shown). The image presentation matrix 1 and the edges 2, 3 and the edges which are not shown, 4, 5, are fully covered by the front pane 10. The contact surfaces 19, 20, 21, 22 are partly covered by the front pane. Formed between the front pane 10 and the fastening element 6 is a gap 40, and between the front pane 10 and the fastening element 7 a gap 41. Accordingly, the front pane 10 can be displaced in the x-direction and the y-direction, wherein the x-direction and the y-direction are shown in the co-ordinate system shown at the bottom left. Likewise, the front pane is rotatable about a z-axis when gaps are present between the front pane and the fastening elements.

The fastening elements 6 and 7 comprise threaded holes 43. FIG. 4 shows how a clamping strip 11 is located at the fastening element 6. The clamping strip 11 is fixed with screws (not shown), which are guided through holes 44 in the clamping strip 11 and are screwed into the threaded holes 43 of the fastening element 6. The clamping strip 11 presses the front pane 10 against the contact surface 19. Because the holes 44 are conically shaped, countersunk screws can be used, which in the inserted state end flush with the surface of the clamping strip 11. In the same way, the clamping strip 12, which presses the front pane 10 against the contact surface 20, is secured to the fastening element 7. Further clamping strips, not shown, 13 and 14 are secured to fastening elements, not shown, 8 and 9, which are provided on profile strips 17 and 18.

FIG. 6 shows a section from FIG. 4 in a somewhat rotated perspective for better illustration of the three-dimensional structure. As also in FIG. 5, the extension of the profile strips 15 and 16 in the z-direction can be seen.

Shown in FIG. 7 is a further view of the arrangement, viewed obliquely from above, wherein the profile strip 15 and the clamping strip 11 have been left out in order to illustrate the arrangement better.

FIG. 8 shows a view in the y-direction onto the structure from FIG. 7. In FIGS. 7 and 8, in turn the spatial extent of the profile strip 16 in the z-direction can be seen. The fastening element 7 comprises a spacer element 36, which at the fastening element 7 delimits the flank which protrudes laterally. The spacer element 36 partially covers the edge 3 of the image presentation matrix 1. In the special embodiment, the spacer element 36 extends along the entire edge 3 and, respectively, over the entire length of the profile strip (see FIG. 5), such that the spacer element 36 is arranged not only in the region of the fastening element 7. Arranged on the face side of the spacer element 36 is the contact surface 20 for the front pane 10. Shown in FIG. 8 is a grub screw 50, which penetrates a tapering end 51 of the fastening element 7 and is in contact at the edge of the front pane 10. By means of the grub screw 50 or, respectively, by means of several grub screws 50 arranged at the fastening element 6, 7, 8, 9 in the same manner, the front pane 10 can be adjusted in the x-direction and y-direction, since a gap 41 is formed between the front pane 10 and the fastening element 7 or its tapering end 51 respectively. For the adjustment, as far as may be necessary, the clamping strip 12 can be somewhat loosened. An intermediate element can be provided between the grub screw 50 and the front pane 10, in particular made of a flexible, deformable material, in order to protect the front pane 10 against damage due to the screw. In the same way, a flexible, preferably also slip-inhibiting material can be provided between the front pane 10 and the clamping strip 12. A flexible, slip-inhibiting material can also be arranged between the front pane 10 and the contact surface 20.

In FIG. 8 it can be seen that the profile strip 16 is partly in contact laterally at the housing 60. It can be secured to the housing 60 in various ways, such as by adhesive or screw connection.

FIGS. 9 and 10 show from two different perspectives, from obliquely above and from the y-direction (parallel to the image presentation matrix 1), a further embodiment of a profile strip 80. The profile strip 80 has a part 81 protruding in the z-direction, which serves as a spacer element, and a limb 82, which is secured laterally at the housing 60 of the image presentation matrix 1. The parts 81 and 82 are not separated or separable elements, but are formed in one piece (integral), for example from plastic or metal. In this embodiment, a fastening element 83, by contrast with the embodiment from FIGS. 7 and 8, does not form an integral constituent part of the profile strip, and is therefore not a formed part of the profile. Instead, the fastening element 83 is secured as a separate part to the profile strip, in this case by a screw connection. The fastening element 83 has an L-shape (angle) with a first longer limb 84 and a shorter limb 85. The fastening element 83 is screwed by the first limb 84 laterally to the profile strip 80 with a screw 86. The limb 84 exhibits a longitudinal hole 87, through which the profile strip 80 is rotated in. Thanks to the longitudinal hole, the limb 84 can be moved in the z-direction, and can be moved sufficiently far for the short limb 85, which is in contact with the front pane 10, to press the front pane 10 against the contact surface 20 at the profile strip. The limb 85 of the fastening element 85 exerts pressure onto the front pane 10 in the direction of the image presentation matrix 1, and secures the front pane in its position. The longer limb 84 forms a lateral flank and delimitation for the front pane.

Shown in FIG. 10 is a grub screw 50, which penetrates the limb 84 of the fastening element 83 and is in contact at the edge of the front pane 10. By means of the grub screw 50, the front pane 10 can be adjusted in the x-direction (or, with other fastening elements which are rotated through 90° in relation to the element 83, in the y-direction), since a gap 41 is formed between the front pane 10 and the limb 84. For the adjustment, the screw 86 can be loosened somewhat, as far as is necessary. An intermediate element can be provided between the grub screw 50 and the front pane 10, in particular of a flexible, deformable material, in order to protect the front pane 10 against damage by the screw 50. A soft, slip-inhibiting material can be arranged between the limb 85 and the front pane. Likewise, a soft, slippage-inhibiting material can be arranged between the profile strip and the front pane.

Starting from a section shown of an image reproduction assembly from FIG. 4, FIG. 11 shows an assembly 70 of several image reproduction assemblies, wherein four image reproduction assemblies are shown, which have a rectangular shape and abut at a common corner and of which the edges are arranged parallel to one another.

FIG. 12 shows an enlarged section, wherein one of the image representation assemblies is shown in full in the lower left area of FIG. 12. With all the image representation assemblies, the fastening elements of clamping strips 11, 12, 13, 14 are covered, wherein the fastening elements are in each case arranged behind the projections of the clamping strips 11, 12, 13, 14, identifiable at the regions between the holes 44. In FIG. 12 it can clearly be seen that the fastening elements are arranged along the edges (covered) in such a way that recesses 90 are provided between fastening elements. By way of example, this is shown at the lower edge of the fully represented image reproduction assembly in FIG. 12, bottom left, where recesses 90 are formed between fastening elements 8, wherein the fastening elements 8 are in turn covered by the clamping strip 13. The clamping strip 13 comprises corresponding recesses and, respectively, matches the shape of the recesses 90. The recess 90 at the bottom right in FIG. 12 delimits the fastening element 8 and is not arranged between two fastening elements 8.

In FIG. 11 it can be seen that the fastening element arranged behind the clamping strip (compare with FIG. 3) engages in the recess 90. In an analogous manner, further fastening elements, which are arranged along the same or other edges, engage in recesses 90. The recesses 90 in this embodiment are wider than the fastening elements or, respectively, the projections of the clamping strips forming the fastening elements, such that the individual arrangements are somewhat capable of being moved in relation to one another. Due to the fact that the fastening elements and the protruding parts of the clamping strip 11, 12, 13, 14 engage in each case into an allocated recess 90, the overall width of the transition (web) between two image presentation matrices is minimised.

Viewed from the z-direction, the shapes of the clamping strips 11, 12, 13, 14 correspond to the shapes of the profile strips 15, 16, 17, 18 which are covered by them. The edges 2, 3, 4, 5, which are covered by the profile strips 15, 16, 17, 18 and the clamping strips 11, 12, 13, 14, are indicated by arrows in FIG. 12 and designated by 2, 3, 4, 5. Profile strips 15 and 17 are arranged at opposing edges 2 and 4, arranged point-symmetrically about the point P, which lies at the intersection of the wide diagonals of the rectangular image presentation matrix 1, here covered by the front pane 10. In an analogous manner, the profile strips 16 and 18 and the clamping strips 12 and 14 are arranged point-symmetrically to one another. This means that the clamping strips 11 and 13 are identical, the clamping strips 12 and 14 are identical, the profile strips 15 and 17, which are covered by the clamping strips 11 and 13, are identical to one another, and the profile strips 16 and 18, which are covered by the clamping strips 12 and 14, are identical to one another. Because the profile strips arranged at opposing edges are arranged point-symmetrically to one another, the fastening elements provided on the profile strips are also arranged point-symmetrically to one another at the point P.

1.-11. (canceled)

12. An image reproduction assembly comprising:
a two-dimensional image presentation matrix delimited by edges and by the matrix elements of which images can be presented;
fastening elements arranged adjacent to the edges of the image presentation matrix;
a front pane which is secured to the fastening elements and is fixed in a plane in front of the image presentation matrix;
wherein each fastening element protrudes at least partially beyond the plane of the image presentation matrix;
wherein each fastening element protrudes at least partially beyond the edges of the image presentation matrix transversely to the viewing direction of an observer; and
wherein the fastening elements are arranged along the edges in such a way that recesses are present between fastening elements and/or adjacent to one or more fastening elements,
and wherein an arrangement of several such image reproduction assemblies next to and/or above one another;
wherein the fastening elements of a first image reproduction assembly can be positioned in the recesses of one or more image reproduction assemblies adjacent to the first image reproduction assembly; and
wherein the fastening elements of one or more image reproduction assemblies adjacent to the first image reproduction assembly can be positioned in the recesses of the first image reproduction assembly.

13. An image reproduction assembly according to claim 12, wherein fastening elements arranged at opposing edges are arranged point-symmetrically to one another about a point (P), which lies on the intersection of the two diagonals of the rectangular image presentation matrix.

14. An image reproduction assembly according to claim 12, wherein the fastening elements comprise clamping elements and exert a pressure onto the front pane in the direction of the image presentation matrix.

15. An image reproduction assembly according to claim 12,
wherein the fastening elements are arranged in an L-shape;
wherein one limb of the L-shaped fastening element is located at the side of the housing of the image presentation matrix;
wherein it is in contact directly or indirectly with the housing; and
wherein a second limb is in contact directly or indirectly with the front pane and exerts a pressure onto the front pane in the direction of the image presentation matrix.

16. An image reproduction assembly according to claim 12, comprising spacer elements, by means of which the front pane can be positioned at a distance from the image presentation matrix.

17. An image reproduction assembly according to claim 12,
wherein the fastening elements comprise adjustment means with which the front pane can be at least one of moved or rotated parallel to the plane of the image presentation matrix.

18. An image reproduction assembly according to claim 12, further comprising profile strips which are arranged along the edges of the image presentation matrix, wherein each profile strip comprises a contact surface for the front pane, which is arranged parallel to the plane of the image presentation matrix; and
wherein the fastening elements are located on the profile strips or are formed as integral parts on the profile strips.

19. An image reproduction assembly according to claim 18, wherein the profile strips comprise fastening elements with clamping elements; and
wherein the clamping elements exert a pressure onto the front pane in the direction of the image presentation matrix.

20. An image reproduction assembly according to claim 18,
wherein the profile strips comprise fastening elements which are designed as L-shaped;
wherein one limb of the L-shaped fastening element is located laterally at the profile strip; and
wherein a second limb is located on the front pane and exerts a pressure onto the front pane in the direction of the image presentation matrix.

21. An image reproduction assembly according to claim 18, wherein the profile strips are identical and are located opposite one another and arranged at opposite edges of the image presentation matrix.

22. An arrangement of several image reproduction assemblies according to claim 12, wherein several image reproduction assemblies are arranged next to or above one another such that the individual image presentation matrices of the image reproduction assembly are brought together to form one enlarged image presentation matrix.

23. An image reproduction assembly according to claim 13, wherein the fastening elements comprise clamping elements and exert a pressure onto the front pane in the direction of the image presentation matrix.

24. An image reproduction assembly according to claim 13,
wherein the fastening elements are arranged in an L-shape;
wherein one limb of the L-shaped fastening element is located at the side of the housing of the image presentation matrix;
wherein it is in contact directly or indirectly with the housing; and
wherein a second limb is in contact directly or indirectly with the front pane and exerts a pressure onto the front pane in the direction of the image presentation matrix.

25. An image reproduction assembly according to claim 13, comprising spacer elements, by means of which the front pane can be positioned at a distance from the image presentation matrix.

26. An image reproduction assembly according to claim 13,
wherein the fastening elements comprise adjustment means with which the front pane can be at least one of moved or rotated parallel to the plane of the image presentation matrix.

27. An image reproduction assembly according to claim 13, further comprising profile strips which are arranged along the edges of the image presentation matrix, wherein each profile strip comprises a contact surface for the front pane, which is arranged parallel to the plane of the image presentation matrix; and
wherein the fastening elements are located on the profile strips or are formed as integral parts on the profile strips.

28. An image reproduction assembly according to claim 27, wherein the profile strips comprise fastening elements with clamping elements; and
wherein the clamping elements exert a pressure onto the front pane in the direction of the image presentation matrix.

29. An image reproduction assembly according to claim 27,
wherein the profile strips comprise fastening elements which are designed as L-shaped;
wherein one limb of the L-shaped fastening element is located laterally at the profile strip; and
wherein a second limb is located on the front pane and exerts a pressure onto the front pane in the direction of the image presentation matrix.

30. An image reproduction assembly according to claim 27, wherein the profile strips are identical and are located opposite one another and arranged at opposite edges of the image presentation matrix.

31. An arrangement of several image reproduction assemblies according to claim 13, wherein several image reproduction assemblies are arranged next to or above one another such that the individual image presentation matrices of the image reproduction assembly are brought together to form one enlarged image presentation matrix.
